(19) United States
(12) Patent Application Publication
(10) Pub. No.: US 2002/0142553 A1
(43) Pub. Date: Oct. 3, 2002

(54) Method of forming an ultra-shallow junction

(76) Inventor: Jason J.S. Jenq, Pingtung (TW)

Correspondence Address: J.C. Patents, Inc., 4 Venture, Suite 250, Irvine, CA, 92618, US

(21) Appl. No.: 09/829,289

(22) Filed: Apr. 9, 2001

(30) Foreign Application Priority Data
Apr. 2, 2001 (TW) 90107850

(51) Int. Cl. H01L 21/336

(52) U.S. Cl. 438/301

(57) ABSTRACT

A method of forming an ultra-shallow junction. An amorphous silicon layer first is formed in a surface of a substrate. Then, boron ions are implanted into the amorphous silicon layer, followed by implanting germanium ions into the amorphous silicon layer. A low temperature solid phase epitaxial re-growth (LTSPER) process is carried out to re-crystallize the amorphous silicon layer. Then, boron ions are implanted into the surface of the substrate before an activation so that an ultra-shallow junction is formed.

### CROSS-REFERENCE TO RELATED APPLICATION

This application claims the priority benefit of Taiwan application serial no. 90107850, filed on Apr. 2, 2001.

### BACKGROUND OF THE INVENTION

1. Field of Invention

The present invention relates generally to a method of fabricating semiconductor. More particularly, the present invention relates to a method of forming an ultra-shallow junction.

2. Description of the Related Art

With recent advances in semiconductor fabrication technology and increasing demand for smaller-sized semiconductor applications, the depth of the S/D junction of the metal oxide semiconductor (MOS) transistor needs to be decreased in order to prevent a short channel effect from occurring, and to reduce the punch-through current. However, once the depth of the S/D junction of the MOS transistor is decreased, the doping concentration must be increased in order to prevent the resistance of the S/D junction, which in turn reduces the efficiency of the MOS device.

To solve the above-described problems, a high dosage of ions is used by a conventional method during the implant process. However, the high dosage of ions can damage the junction profile of a crystallized silicon substrate and increase the junction leakage. Moreover, in an advanced fabrication process, the doping concentration of the S/D junction is nearly a saturated solid solubility, so the method of implanting a high dosage of ions cannot be used.

Another conventional method is used to solve the foregoing problem by utilizing a low temperature solid phase epitaxial re-growth (LTSPER) process. In this method, silicon ions first are implanted into a top surface of a silicon substrate in order to amorphize it. Next, the doping ions are implanted into the amorphous silicon layer. Then, a LTSPER process is carried out to re-crystallize the amorphous silicon layer, and the doping ions are implanted actively. Thus an ultra-shallow junction is formed. The LTSPER process produces a good junction profile so that the junction leakage can be prevented, and since the concentration of the dopant of ultra-shallow junction reaches a saturation status, the resistance of the device is reduced.

Although the LTSPER process has the above-mentioned advantages, the silicon dopant of the ultra-shallow junction will deactivate during the later fabrication process when the temperature is above 700° C., and the quality of the device will then be affected.

### SUMMARY OF THE INVENTION

It is an object of the present invention to provide a method of forming an ultra-shallow junction that can resolve the above-mentioned problem. The steps of the method comprise: first forming an amorphous silicon layer in a surface of a substrate; implanting boron ions into the amorphous silicon layer, followed by implanting germanium ions into the amorphous silicon layer; performing a low temperature solid phase epitaxial regrowth (LTSPER) process to re-crystallize the amorphous silicon layer; and implanting boron ions into the surface of the substrate before an activation so that an ultra-shallow junction is formed.

In the step of implanting germanium ions, the deactivation temperature of the boron dopant is increased to 700° C., so that the deactivation of the boron dopant in the ultra-shallow junction can be prevented during the later fabrication process.

Both the foregoing general description and the following detailed description are exemplary and explanatory only and are not restrictive of the invention, as claimed.

### BRIEF DESCRIPTION OF THE DRAWINGS

The accompanying drawings are included to provide a further understanding of the present invention, and are incorporated in and constitute a part of this specification. The drawings illustrate embodiments of the invention and, together with the description, serve to explain the principles of the invention. In the drawings,

FIGS. 1A to 1D are schematic views of a method of forming an ultra-shallow junction in accordance with a preferred embodiment of the present invention.

### DESCRIPTION OF THE PREFERRED EMBODIMENTS

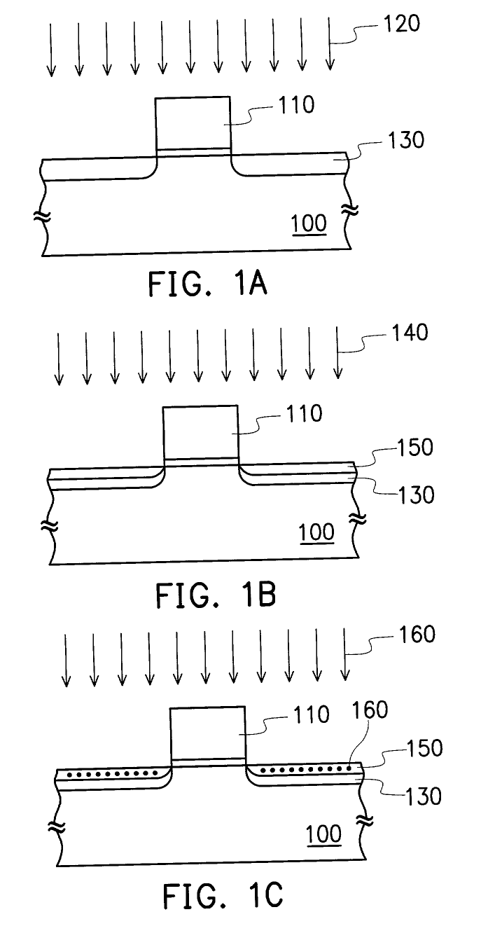

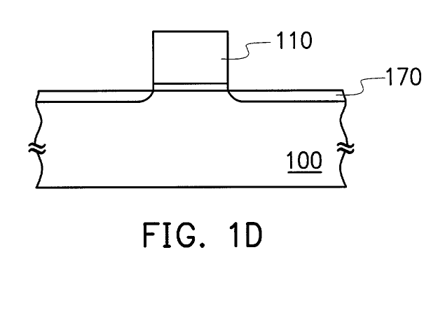

Referring to FIG. 1, a substrate 100 is first provided and a gate 110 is formed thereon. The gate 110 is utilized as a mask to implant silicon ions 120 into an exposed surface region of the substrate 100 in order to form an amorphous silicon layer 130. The silicon ions 120 are implanted with a dosage approximately between 5×10¹⁴/cm² to 2×10¹⁵/cm², in which an implanted energy is about 30 KeV. The implanting step of forming the amorphous silicon layer is not limited to silicon ions only; argon ions (Ar⁺) also can be utilized.

Referring to FIG. 1B, boron ions 140 are implanted into the amorphous silicon layer 130 to form a boron doped region 150. An implanting dosage of the boron ions 140 is approximately between 5×10¹⁴/cm² to 8×10⁵/cm², and an implanting energy of the boron ions 140 is about 5 KeV. A depth of implanting boron ions 140 with 5 KeV energy into the amorphous layer 130 is approximately between 200 Å to 400 Å of an ultra junction. This step of forming the boron doped region 150 can be carried out by implanting boron fluoride (BF₂⁺) ions, but in order to have the same depth as the ultra junction, the energy of the boron fluoride (BF₂⁺) ions has to be higher than the boron ions.

Referring to Fig. IC, germanium ions 160, which are implanted into the boron doped region 150, have a dosage of approximately between 1×10¹⁴1 cm² to 6×10⁴/cm², and the implanting energy is approximately between 0.5 KeV to 2.0 KeV. The purpose of implanting the germanium ions 160 is to reduce stress of the lattice structure and delay the deactive reaction of the boron dopant.

Referring to FIG. 1D, a low temperature solid phase epitaxial re-growth (LTSPER) process is performed to re-crystallize the amorphous silicon layer 130 (because the characteristic of the re-crystallized amorphous silicon layer is the same as the substrate 100, it is not shown in the figures.) and to activate the boron dopant in the boron doped region 150. Next, an ultra-shallow junction 170 is formed in the surface of the substrate 100 by the LTSPER process, which is performed at a temperature of approximately between 500° C. and 600° C.

According to the above-mentioned, the present invention firstly implants germanium ions in the boron doped region, followed by performing the LTSPER process to form the ultra-shallow junction. The method of forming the ultra-shallow junction of the present invention has the advantages of preventing current leakage and high resistance. The temperature of the boron dopant in the inactive reaction can be increased to above 700° C., which provides the advantage of preventing the inactive reaction from occurring in the ultra-shallow junction. Thus the reliability of the device is improved.

Other embodiments of the invention will appear to those skilled in the art from consideration of the specification and practice of the invention disclosed herein. It is intended that the specification and examples to be considered as exemplary only, with a true scope and spirit of the invention being indicated by the following claims.

What is claimed is:

1. A method of forming an ultra-shallow junction, wherein the steps of the method comprise:
providing a substrate;
amorphizing a surface of the substrate to form an amorphous silicon layer;
implanting boron ions into the amorphous silicon layer;
implanting germanium ions into the amorphous silicon layer; and
performing a low temperature solid phase epitaxial re-growth (LTSPER) process to re-crystallize the amorphous silicon layer and activate the implanted boron ions so that an ultra-shallow junction is formed in the surface of the substrate.

2. The method of claim 1, wherein the step of implanting the germanium ions is performed with a dosage of approximately between 1×10¹⁴/cm² and 6×10¹⁴/cm².

3. The method of claim 1, wherein the germanium ions are implanted with an energy of approximately between 0.5 KeV and 2.0 KeV.

4. The method of claim 1, wherein the step of implanting the boron ions is performed with a dosage of approximately between 5×10⁴/cm² and 8×10⁵/cm².

5. The method of claim 1, wherein the step of implanting the boron ions is performed with an energy of approximately 5 KeV.

6. The method of claim 1, wherein a depth of the ultra-shallow junction is approximately between 200 Å to 400 Å.

7. The method of claim 1, wherein the step of performing the LTSPER process is carried out at a temperature of approximately between 500° C. and 600° C.

8. The method of claim 1, wherein the step of forming the amorphous silicon layer further comprises implanting silicon ions.

9. The method of claim 8, wherein an implanted dosage of the silicon ions is approximately between 5×10⁴/cm² and 2×10¹⁵/cm².

10. The method of claim 8, wherein the silicon ions are implanted with an energy of approximately 30 KeV.

11. The method of claim 1, wherein the step of forming the amorphous silicon layer further comprises implanting fluoride ions.

12. A method of forming an ultra-shallow junction, the steps of the method comprising:
providing a substrate;
amorphizing a surface of the substrate to form an amorphous silicon layer;
implanting boron fluoride ions in the amorphous silicon layer;
implanting germanium ions in the amorphous silicon layer; and
performing a low temperature solid phase epitaxial re-growth (LTSPER) process to re-crystallize the amorphous silicon layer and activate the implanted boron ions so that an ultra-shallow junction is formed in the surface of the substrate.

13. The method of claim 12, wherein the step of implanting the germanium ions is performed with a dosage of approximately between 1×10¹⁴/cm² and 6×10¹⁴/cm².

14. The method of claim 12, wherein the germanium ions are implanted with an energy of approximately between 0.5 KeV and 2.0 KeV.

15. The method of claim 12, wherein the step of implanting the boron fluoride ions is performed with a dosage of approximately between 5×10⁴/cm² and 8×10¹⁵/cm².

16. The method of claim 12, wherein the step of performing the LTSPER process is carried out at a temperature of approximately between 500° C. and 600° C.

17. The method of claim 12, wherein the step of forming the amorphous silicon layer further comprises implanting silicon ions.

18. The method of claim 17, wherein an implanted dosage of the silicon ions is approximately between 5×10⁴/cm² and 2×10¹⁵/cm².

19. The method of claim 17, wherein the silicon ions are implanted with an energy of approximately 30 KeV.

20. The method of claim 12, wherein the step of forming the amorphous silicon layer further comprises implanting fluoride ions.
